(19) United States
(12) Patent Application Publication
(10) Pub. No.: US 2012/0034731 A1
(43) Pub. Date: Feb. 9, 2012

(54) PHOTOELECTRIC CONVERSION DEVICE MANUFACTURING SYSTEM AND PHOTOELECTRIC CONVERSION DEVICE MANUFACTURING METHOD

(75) Inventors: Takafumi Noguchi, Chigasaki-shi (JP); Hideyuki Ogata, Chigasaki-shi (JP); Katsuhiko Mori, Chigasaki-shi (JP); Yasuo Shimizu, Chigasaki-shi (JP); Hiroto Uchida, Chigasaki-shi (JP); Shin Asari, Sammu-shi (JP)

(73) Assignee: ULVAC, INC., Chigasaki-shi (JP)

(21) Appl. No.: 13/262,758

(22) PCT Filed: Apr. 6, 2010
(86) PCT No.: PCT/JP2010/002506

§ 371 Date: Oct. 3, 2011

(30) Foreign Application Priority Data
Apr. 6, 2009 (JP) 2009-092455

(51) Int. Cl. H01L 31/18; H01L 31/105

(52) U.S. Cl. 438/87; 118/719; 257/E31.061

(57) ABSTRACT

A photoelectric conversion device manufacturing system in which a photoelectric conversion device is manufactured, the photoelectric conversion device including a p-type semiconductor layer, an i-type semiconductor layer, and an n-type semiconductor layer which are sequentially layered on a transparent-electroconductive film formed on a substrate in the photoelectric conversion device. The system includes: an i-layer-formation reaction chamber comprising at least a first film formation section, a second film formation section, and a third film formation section, the i-layer-formation reaction chamber forming the i-type semiconductor layer, the first film formation section, the second film formation section, and the third film formation section being sequentially arranged along a transfer direction in which the substrate is transferred; and a plurality of door valves separating the first film formation section, the second film formation section, and the third film formation section so that the length of the second film formation section is greater than the lengths of the first film formation section and the third film formation section in the transfer direction.

### BACKGROUND OF THE INVENTION

1. Field of the Invention

The present invention relates to a photoelectric conversion device manufacturing system and a photoelectric conversion device manufacturing method.

Particularly, the invention relates to a technique for obtaining an excellent efficiency in a tandem-type photoelectric conversion device in which two photoelectric conversion units are layered.

This application claims priority from Japanese Patent Application No. 2009-092455 filed on Apr. 6, 2009, the contents of which are incorporated herein by reference in their entirety.

2. Background Art

In recent years, the photoelectric conversion devices have been widely used for solar cells, photodetectors, and the like, in particular, in view of efficient use of energy, solar cells are more widely used than ever before.

Specifically, a photoelectric conversion device in which single crystal silicon is utilized has a high level of energy conversion efficiency per unit area.

However, in contrast, in the photoelectric conversion device in which the silicon single crystal is utilized, a single crystal silicon ingot is sliced, a sliced silicon wafer is used in the solar cell; therefore, a large amount of energy is spent for manufacturing the ingot, and the manufacturing cost is high.

For example, at the moment, in a case of realizing a photoelectric conversion device having a large area which is placed outdoors or the like, when being manufactured by use of single crystal silicon, the cost considerably increases.

Consequently, as a low-cost photoelectric conversion device, a photoelectric conversion device that can be further inexpensively manufactured and that employs a thin film made of amorphous silicon (hereinafter, refer to “a-Si thin film”) is in widespread use.

However, conversion efficiency of a photoelectric conversion device in which an amorphous-silicon thin film is utilized is lower than the conversion efficiency of a crystalline photoelectric conversion device in which single-crystalline silicon, polysilicon, microcrystalline silicon existing in amorphous silicon or the like is utilized.

For this reason, as a structure for improving the conversion efficiency of the photoelectric conversion device, a multi-junction structure, such as a tandem-type, a triple-type, or the like, in which two or more photoelectric conversion units are stacked in layers has been proposed.

For example, as shown in FIG. 7, a tandem-type photoelectric conversion device 100 is known.

In the photoelectric conversion device 100, a transparent substrate 101 having an insulation property, on which a transparent-electroconductive film 102 is disposed, is employed.

A pin-type first-photoelectric conversion unit 103 that is obtained by stacking a p-type semiconductor layer 131 (p-layer), an i-type silicon layer 132 (amorphous silicon layer, i-layer), and an n-type semiconductor layer 133 (n-layer) in this order is formed on the transparent-electroconductive film 102.

A pin-type second-photoelectric conversion unit 104 that is obtained by stacking a p-type semiconductor layer 141 (p-layer), an i-type silicon layer 142 (crystalline-silicon layer, i-layer), and an n-type semiconductor layer 143 (n-layer) in this order is formed on the first-photoelectric conversion unit 103.

Additionally, a back-face electrode 105 is formed on the second-photoelectric conversion unit 104.

In addition, a tandem-type photoelectric conversion device in which an i-type layer of a second photoelectric conversion unit is formed of an amorphous silicon layer or an amorphous silicon-germanium layer is known.

Furthermore, a triple-type photoelectric conversion device in which an amorphous silicon layer or a crystalline silicon layer that serves as a third photoelectric conversion unit layer is layered on a second photoelectric conversion unit is known.

In the foregoing structure, improvement in a conversion efficiency is achieved.

As a method for manufacturing the foregoing tandem-type photoelectric conversion device, a manufacturing method disclosed in Japanese Patent No. 3589581 is known.

In the manufacturing method, a plasma CVD reaction chamber is used which corresponds to each of a p-type semiconductor layer, an i-type-amorphous-silicon-based photoelectric conversion layer, and an n-type semiconductor layer constituting an amorphous-type photoelectric conversion unit (first photoelectric conversion unit); and one layer is formed in each reaction chamber.

In particular, a plurality of layers are formed by using a plurality of plasma CVD reaction chambers which are different from each other.

Additionally, in the manufacturing method, a p-type semiconductor layer, an i-type-crystalline silicon-based photoelectric conversion layer, and an n-type semiconductor layer which constitute a crystalline-type photoelectric conversion unit (second-photoelectric conversion unit) are formed in the same plasma-CVD reaction chamber.

In a method for manufacturing for the tandem-type photoelectric conversion device 100, as shown in FIG. 8A, firstly, an insulative-transparent substrate 101 on which a transparent-electroconductive film 102 is formed is prepared.

Next, as shown in FIG. 8B, the p-layer 131, the i-layer 132, and the n-layer 133 are sequentially formed on the transparent-electroconductive film 102 formed on the insulative-transparent substrate 101.

Here, one of layers 131, 132, and 133 is formed in one plasma CVD reaction chamber.

That is, the layers 131, 132, and 133 are formed by using a plurality of the plasma CVD reaction chambers which are different from each other.

Consequently, a pin-type first-photoelectric conversion unit 103 in which layers are sequentially stacked is formed on the insulative-transparent substrate 101.

Continuously, as shown in FIG. 8C, the p-layer 141, the i-layer 142, and the n-layer 143 are formed on the n-layer 133 of the first photoelectric conversion unit 103 in the same plasma CVD reaction chamber.

For this reason, a pin-type second-photoelectric conversion unit 104 in which layers are sequentially stacked is formed.

Consequently, due to forming a back-face electrode 105 on the n-layer 143 of the second-photoelectric conversion unit 104, a photoelectric conversion device 100 is obtained as shown in FIG. 7.

The tandem-type photoelectric conversion device 100 having the above-described structure is manufactured by, for example, the following manufacturing system.

In this manufacturing system, a first-photoelectric conversion unit 103 is formed by use of a so-called in-line type first film-formation apparatus, in which a plurality of film-formation reaction chambers which are referred to as chamber are disposed so as to be linearly connected (linear arrangement).

A plurality of the layers constituting the first photoelectric conversion unit 103 are formed in a plurality of film-formation reaction chambers in the first film-formation apparatus.

In particular, one layer constituting the first photoelectric conversion unit 103 is formed in each of the film-formation reaction chambers which are different from each other.

After the first-photoelectric conversion unit 103 is formed, a second-photoelectric conversion unit 104 is formed by use of a so-called in-line type second film-formation apparatus.

A plurality of layers constituting the second-photoelectric conversion unit 104 are formed in a plurality of film-formation reaction chambers in the second film-formation apparatus.

In particular, one layer constituting the second photoelectric conversion unit 104 is formed in each of the film-formation reaction chambers which are different from each other.

Specifically, the manufacturing system includes a first film-formation apparatus 160 and a second film-formation apparatus 170 connected to the first film-formation apparatus 160 as shown in, for example, FIG. 9.

In the first film-formation apparatus 160, a load chamber 161 (L: Lord), a P-layer film-formation reaction chamber 162, an I-layer film-formation reaction chamber 163, and an N-layer film-formation reaction chamber 164 are continuously and linearly arranged.

In the second film-formation apparatus 170, a P-layer film-formation reaction chamber 171, an I-layer film-formation reaction chamber 172, an N-layer film-formation reaction chamber 173, and an unload chamber 174 (UL: Unlord) are continuously and linearly arranged.

In the manufacturing system, firstly, a substrate is transferred to the load chamber 161 and is disposed therein, and the internal pressure of the load chamber 161 is reduced.

Continuously, while the reduced-pressure atmosphere is maintained, the p-layer 131 of the first-photoelectric conversion unit 103 is formed in the P-layer film-formation reaction chamber 162, the i-layer 132 is formed in the I-layer film-formation reaction chambers 163, and the n-layer 133 is formed in the N-layer film-formation reaction chamber 164.

Furthermore, continuously, the p-layer 141 of the second photoelectric conversion unit 104 is formed on the n-layer 133 of the first photoelectric conversion unit 103 in the P-layer film-formation reaction chamber 171.

Subsequently, the i-layer 142 is formed in the I-layer film-formation reaction chamber 172, and the n-layer 143 is formed in the N-layer film-formation reaction chamber 173.

The substrate on which the second photoelectric conversion unit 104 is formed as described above is transferred to the unload chamber 174, the internal pressure of the unload chamber 174 is returned to an atmospheric pressure.

Finally, the substrate is ejected from the unload chamber 174.

At the G point of the first manufacturing system shown in FIG. 9, the insulative-transparent substrate 101 on which the transparent-electroconductive film 102 is formed is prepared as shown in FIG. 8A.

Additionally, at the H point shown in FIG. 9, a first intermediate part 100a of the photoelectric conversion device in which the first-photoelectric conversion unit 103 is provided is formed on the transparent-electroconductive film 102 formed on the insulative-transparent substrate 101 as shown in FIG. 8B.

Consequently, at the I point shown in FIG. 9, a second intermediate part 100b of the photoelectric conversion device in which the second-photoelectric conversion unit 104 is provided is formed on the first-photoelectric conversion unit 103 as shown in FIG. 8C.

In the in-line type first and second film-formation apparatuses as show in FIG. 9, two substrates are simultaneously processed, the I-layer-formation reaction chamber 163 is constituted of four reaction chambers 163a to 163d, and the I-layer-formation reaction chamber 172 is constituted of four reaction chambers 172a to 172d.

In the conventional manufacturing method using the above-described in-line type film-formation apparatus, the number of needed film forming chambers is varied depending on the film thickness of each layer of the photoelectric conversion device.

For example, an i-layer serving as an amorphous photoelectric conversion layer has the film thickness of 2000 to 3000 Å, and the i-layer can be manufactured in a reaction chamber for exclusive use.

Furthermore, a reaction chamber for exclusive use is employed for each of the p-layer, the i-layer, and the n-layer.

Because of this, impurities in the p-layer are not diffused in the i-layer, or an indistinct junction which is caused by remaining impurities in the reaction chamber being doped into the p-layer or the n-layer is not generated.

For this reason, an excellent impurity profile in a pin-junction structure is obtained.

On the other hand, the film thickness of the i-layer serving as a crystalline photoelectric conversion layer is required such as 15000 to 25000 Å so as to be one-digit thicker than that of an amorphous photoelectric conversion layer.

Consequently, in order to improve productivity, a batch type reaction chamber is advantageous in which a plurality of substrates is disposed and simultaneously processed.

In FIG. 9, the I-layer film-formation reaction chamber 163 is constituted of, for example, four reaction chambers 163a to 163d.

The atmospheres in the four reaction chambers 163a to 163d are basically same.

In the foregoing conventional film-formation apparatus, the door valves DV are provided between the reaction chambers 163a to 163d so as to be separated.

However, there is a concern that a difference in pressure occurs as a result of an opening-closing operation of the door valve and the pressure inside of the reaction chambers becomes unstable when substrates are transferred between the reaction chambers.

Additionally, even when a difference in pressure slightly occurs between the reaction chambers to which the substrates are transferred, there is a concern that aerial current is generated at the time of opening the door valve, and a film which has already adhered to an inner wall of the film forming chamber is peeled off or particles flying in all directions.

Furthermore, there is a problem in that time is loss due to an opening-closing operation of the door valves (degradation of throughput), and the cost of the apparatus increases due to providing a chamber mechanism such as an evacuation mechanism or the like for each of the reaction chambers.

Additionally, there is also a problem in that there is an increase in the risk of the apparatus breaking down.

As a result, it is difficult to improve the productivity.

### SUMMARY OF THE INVENTION

The invention was made in order to solve the above problems, and has a first object to provide a photoelectric conversion device manufacturing system which can stably form an i-layer constituting a first photoelectric conversion unit or a second photoelectric conversion unit in a tandem-type photoelectric conversion device with a low amount of impurities, can achieve a high throughput, and can reduce the cost of the apparatus or the risk of the apparatus breaking down.

Additionally, the invention has a second object to provide a photoelectric conversion device manufacturing method can stably form an i-layer constituting a first photoelectric conversion unit or a second photoelectric conversion unit in a tandem-type photoelectric conversion device with a low amount of impurities, and can achieve a high throughput.

A photoelectric conversion device manufacturing system of a first aspect of the invention in which a photoelectric conversion device is manufactured. In the photoelectric conversion device, a p-type semiconductor layer, an i-type semiconductor layer, and an n-type semiconductor layer are sequentially layered on a transparent-electroconductive film formed on a substrate.

The manufacturing system includes: an i-layer-formation reaction chamber (plasma CVD reaction chamber) including at least a first film formation section, a second film formation section, and a third film formation section, the i-layer-formation reaction chamber forming the i-type semiconductor layer, the first film formation section, the second film formation section, and the third film formation section being sequentially arranged along a transfer direction in which the substrate is transferred; and a plurality of door valves separating the first film formation section, the second film formation section, and the third film formation section so that the length of the second film formation section is greater than the lengths of the first film formation section and the third film formation section in the transfer direction.

A photoelectric conversion device manufacturing method of a second aspect of the invention in which a photoelectric conversion device is manufactured. In the photoelectric conversion device, a p-type semiconductor layer, an i-type semiconductor layer, and an n-type semiconductor layer are sequentially layered on a transparent-electroconductive film formed on a substrate.

The manufacturing method includes: preparing an i-layer film-formation reaction chamber (plasma CVD reaction chamber) including at least a first film formation section, a second film formation section, and a third film formation section which are sequentially arranged along a transfer direction in which the substrate is transferred; preparing a plurality of door valves separating the first film formation section, the second film formation section, and the third film formation section so that the length of the second film formation section is greater than the lengths of the first film formation section and the third film formation section in the transfer direction; and forming the i-type semiconductor layer in the second film formation section in a state where the door valve disposed between the first film formation section and the second film formation section and the door valve disposed between the second film formation section and the third film formation section are closed.

It is preferable that the photoelectric conversion device manufacturing method of the second aspect of the invention further include: preparing a p-layer film-formation reaction chamber (plasma CVD reaction chamber) connected to the i-layer-formation reaction chamber at the upstream side in the transfer direction and an upstream door valve provided between the i-layer film-formation reaction chamber and the p-layer film-formation reaction chamber. The upstream door valve is opened and the substrate is transferred from the p-layer film-formation reaction chamber to a film formation section different from the second film formation section during the i-type semiconductor layer being formed in the second film formation section.

Additionally, it is preferable that the film formation section different from the second film formation section be the first film formation section.

It is preferable that the photoelectric conversion device manufacturing method of the second aspect of the invention further include: preparing an n-layer film-formation reaction chamber (plasma CVD reaction chamber) connected to the i-layer-formation reaction chamber at the downstream side in the transfer direction and a downstream door valve provided between the i-layer film-formation reaction chamber and the n-layer film-formation reaction chamber. The downstream door valve is opened and the substrate is transferred from a film formation section different from the second film formation section to the n-layer film-formation reaction chamber during the i-type semiconductor layer being formed in the second film formation section.

Additionally, it is preferable that the film formation section different from the second film formation section be the third film formation section.

Effects of the Invention

In the photoelectric conversion device manufacturing system of the first aspect of the invention, the plasma CVD reaction chamber in which the i-layer is formed is separated into at least three film formation sections (film formation space) by the door valves.

Because of this, it is possible to completely separate the second film formation section located at the middle position in the three film formation sections, the plasma CVD reaction chamber in which the p-layer is formed and which is located in front of the plasma CVD reaction chamber in which the i-layer is formed, and the plasma CVD reaction chamber in which the n-layer is formed and which is located in the rear of the plasma CVD reaction chamber in which the i-layer is formed.

For this reason, it is possible to form the i-layer in the second film formation section located at the middle position between the first film formation section and the third film formation section in a state where the amount of impurities therein is less than that of the first film formation section and the third film formation section.

Additionally, in the photoelectric conversion device manufacturing system of the first aspect of the invention, the length of the second film formation section is greater than the lengths of the first film formation section (a film formation space which is located at a front position) and the third film formation section (a film formation space which is located at a rear position).

For this reason, the volume of the second film formation section is greater than the volumes of the first film formation section and the third film formation section.

Therefore, as compared with a conventional apparatus that is provided with a plurality of film forming chambers separated by the door valves, it is possible to eliminate the difference in pressure which is caused by an opening-closing operation of the door valves, and it is possible to form a film under stabilized pressure.

Furthermore, occurrence of the time loss which is caused by an opening-closing operation of the door valves can be prevented, even when film formation is stopped, it is possible to achieve a high throughput.

In addition, the “film formation is stopped” in this case means the method for forming a film in a state where a substrate faces an electrode and the substrate is static in a film forming chamber.

Generally, in the case of the film formation being stopped, since the time loss occurs due to the above-described opening-closing operation of door valves, it is said that the throughput of the film formation being stopped is degraded as compared with moving film formation in which a film is formed on a substrate which is moved in a film forming chamber.

In contrast, in the invention, it is possible to achieve a high throughput while performing the film formation being stopped.

Additionally, it is possible to reduce the number of chamber mechanism such as an evacuation mechanism or the like due to reducing the number of door valves, and it is possible to reduce the cost of the apparatus or the risk of the apparatus breaking down.

In the photoelectric conversion device manufacturing method of the second aspect of the invention, the i-layer is formed in the second film formation section in a state where the door valve disposed between the first film formation section and the second film formation section and the door valve disposed between the second film formation section and the third film formation section are closed.

Consequently, it is possible to form the i-layer in a state where the three film formation sections are completely separated into the second film formation section located at the middle position, the plasma CVD reaction chamber in which the p-layer is formed and which is located in front of the plasma CVD reaction chamber in which the i-layer is formed, and the plasma CVD reaction chamber in which the n-layer is formed and which is located in the rear of the plasma CVD reaction chamber in which the i-layer is formed.

For this reason, it is possible to form the i-layer in the second film formation section located at the middle position between the first film formation section and the third film formation section, in a state where the amount of impurities therein is less than that of the first film formation section and the third film formation section.

Furthermore, in the photoelectric conversion device manufacturing method of the second aspect of the invention, the door valves separating the first film formation section, the second film formation section, and the third film formation section are used so that the length of the second film formation section is greater than the lengths of the first film formation section and the third film formation section in the transfer direction of the substrate.

For this reason, the volume of the second film formation section is greater than the volumes of the first film formation section and the third film formation section.

Therefore, as compared with a conventional apparatus that is provided with a plurality of film forming chambers separated by the door valves, it is possible to eliminate the difference in pressure which is caused by an opening-closing operation of the door valves, and it is possible to form a film under stabilized pressure.

Additionally, in the photoelectric conversion device manufacturing method of the second aspect of the invention, during the i-layer being formed in the second film formation section, the upstream door valve is opened, and the substrate is transferred from the P-layer film-formation reaction chamber toward the film formation section (first film formation section) different from the second film formation section.

Consequently, it is possible to simultaneously perform a film formation step in the second film formation section and a step of transferring a substrate from the P-layer film-formation reaction chamber to the film formation section different from the second film formation section.

Moreover, the downstream door valve is opened during the i-layer being formed in the second film formation section, and the substrate is transferred from the film formation section (third film formation section) different from the second film formation section to the N-layer film-formation reaction chamber.

Consequently, it is possible to simultaneously perform a film formation step in the second film formation section and a step of transferring a substrate from the film formation section different from the second film formation section to the N-layer film-formation reaction chamber.

As a result, occurrence of the time loss which is caused by an opening-closing operation of the door valves can be prevented, even when film formation is stopped, it is possible to achieve a high throughput.

### BRIEF DESCRIPTION OF THE DRAWINGS

FIG. 1A is a cross-sectional view showing a photoelectric conversion device manufacturing method related to the invention.

FIG. 1B is a cross-sectional view showing the photoelectric conversion device manufacturing method related to the invention.

FIG. 1C is a cross-sectional view showing the photoelectric conversion device manufacturing method related to the invention.

FIG. 2 is a cross-sectional view showing a layered structure of a photoelectric conversion device which is manufactured using the photoelectric conversion device manufacturing method related to the invention.

FIG. 3 is a schematic view showing an example of a manufacturing system manufacturing the photoelectric conversion device related to the invention.

FIG. 4A is a schematic view illustrating an operation in each of reaction chambers of the manufacturing system related to the invention.

FIG. 4B is a schematic view illustrating an operation in each of reaction chambers of the manufacturing system related to the invention.

FIG. 4C is a schematic view illustrating an operation in each of reaction chambers of the manufacturing system related to the invention.

FIG. 4D is a schematic view illustrating an operation in each of reaction chambers of the manufacturing system related to the invention.

FIG. 4E is a schematic view illustrating an operation in each of reaction chambers of the manufacturing system related to the invention.

FIG. 5A is a schematic view illustrating an operation in each of reaction chambers of the manufacturing system related to the invention.

FIG. 5B is a schematic view illustrating an operation in each of reaction chambers of the manufacturing system related to the invention.

FIG. 5C is a schematic view illustrating an operation in each of reaction chambers of the manufacturing system related to the invention.

FIG. 5D is a schematic view illustrating an operation in each of reaction chambers of the manufacturing system related to the invention.

FIG. 5E is a schematic view illustrating an operation in each of reaction chambers of the manufacturing system related to the invention.

FIG. 6A is a schematic view illustrating an operation in each of reaction chambers of the manufacturing system related to the invention.

FIG. 6B is a schematic view illustrating an operation in each of reaction chambers of the manufacturing system related to the invention.

FIG. 7 is a cross-sectional view showing an example of a conventional photoelectric conversion device.

FIG. 8A is a cross-sectional view showing conventional photoelectric conversion device manufacturing method.

FIG. 8B is a cross-sectional view showing conventional photoelectric conversion device manufacturing method.

FIG. 8C is a cross-sectional view showing conventional photoelectric conversion device manufacturing method.

FIG. 9 is a schematic view showing an example of a manufacturing system manufacturing a conventional photoelectric conversion device.

### DESCRIPTION OF THE PREFERRED EMBODIMENTS

Hereinafter, an embodiment of a photoelectric conversion device manufacturing system and a photoelectric conversion device manufacturing method related to the invention will be described with reference to drawings.

In addition, in the respective drawings used in the following explanation, in order to make the respective components be of understandable size in the drawings, the dimensions and the proportions of the respective components are modified as needed compared with the actual components.

In the following explanation, a tandem-type photoelectric conversion device in which a first photoelectric conversion unit and a second photoelectric conversion unit are layered will be described with reference to drawings.

Additionally, an amorphous silicon type photoelectric conversion device is formed as a first photoelectric conversion unit.

Furthermore, a microcrystalline silicon type photoelectric conversion device is formed as a second photoelectric conversion unit.

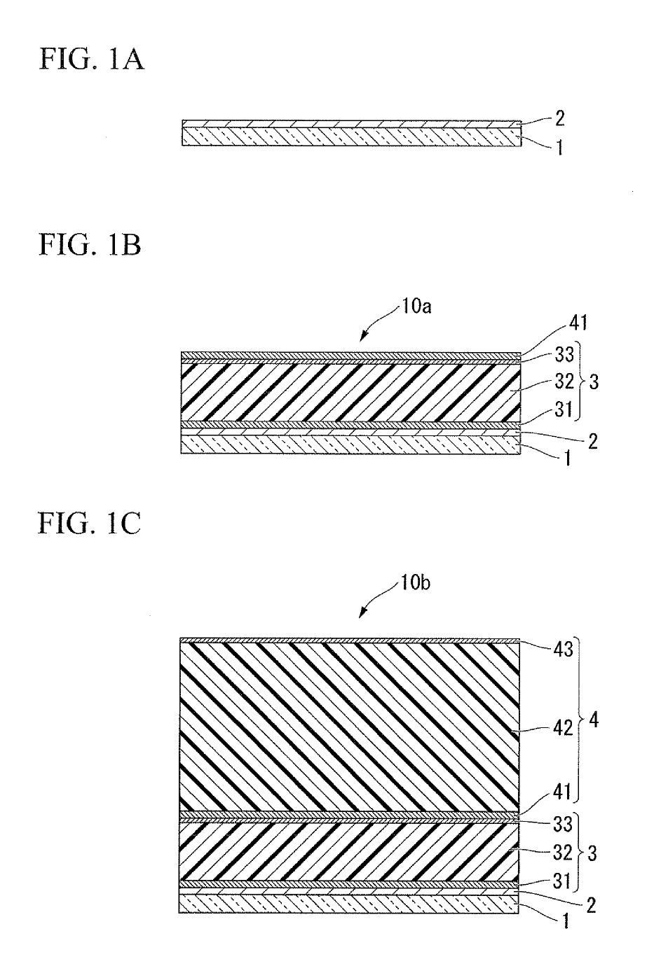

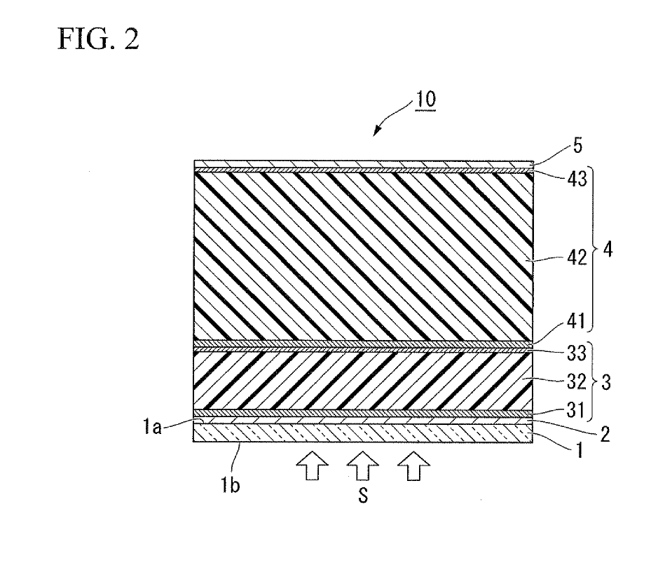

FIGS. 1A to 1C are cross-sectional views showing a photoelectric conversion device manufacturing method related to the invention.

FIG. 2 is a cross-sectional view showing a layered structure of a photoelectric conversion device which is manufactured using the photoelectric conversion device manufacturing method related to the invention.

Photoelectric Conversion Device

Firstly, as shown in FIG. 2, in a photoelectric conversion device 10 which is manufactured using a manufacturing method of the invention, a first photoelectric conversion unit 3 and a second photoelectric conversion unit 4 are formed so as to be layered on a first face 1a (top face) of a substrate 1 in this order.

Furthermore, a back-face electrode 5 is formed on the second photoelectric conversion unit 4.

Each of the first photoelectric conversion unit 3 and the second photoelectric conversion unit 4 includes a pin-type layered structure.

The substrate 1 is a substrate possessing optical transparency and insulation properties and is composed of an insulation material exhibiting an excellent sunlight transparency and durability such as a glass, a transparent resin, or the like.

The substrate 1 is provided with a transparent-electroconductive film 2.

An oxide of metal possessing optical transparency such as ITO (Indium Tin Oxide), SnO₂, ZnO, or the like is adopted as the material of the transparent-electroconductive film 2.

The transparent-electroconductive film 2 is formed on the substrate 1 using a vacuum deposition method or a sputtering method.

In the photoelectric conversion device 10, as indicated by the arrow of FIG. 2, sunlight S is incident to a second face lb of the substrate 1.

Additionally, the first photoelectric conversion unit 3 has a pin structure in which a p-type semiconductor layer 31 (a p-layer, a first p-type semiconductor layer), substantially intrinsic i-type semiconductor layer 32 (an amorphous silicon layer, an i-layer, a first i-type semiconductor layer), and an n-type semiconductor layer 33 (an n-layer, a first n-type semiconductor layer) are stacked in layers.

That is, the first photoelectric conversion unit 3 is formed by stacking the p-layer 31, the i-layer 32, and the n-layer 33 in this order.

The first photoelectric conversion unit 3 is constituted of an amorphous silicon-based material (silicon-based thin film).

In the first photoelectric conversion unit 3, the thickness of the p-layer 31 is, for example, 90 Å, the thickness of the i-layer 32 is, for example, 2500 Å, and the thickness of the n-layer 33 is, for example, 300 Å.

The p-layer 31, the i-layer 32, and the n-layer 33 of the first photoelectric conversion unit 3 are formed in a plurality of plasma CVD reaction chambers.

That is, in each of the plasma CVD reaction chambers which are different from each other, one layer constituting the first photoelectric conversion unit 103 is formed.

Additionally, the second photoelectric conversion unit 4 has a pin structure in which a p-type semiconductor layer 41 (a p-layer, a second p-type semiconductor layer), substantially intrinsic i-type semiconductor layer 42 (a crystalline-silicon layer, an i-layer, a second i-type semiconductor layer), and an n-type semiconductor layer 43 (an n-layer, a second n-type semiconductor layer) are stacked in layers.

That is, the second photoelectric conversion unit 4 is formed by stacking the p-layer 41, the i-layer 42, and the n-layer 43 in this order.

As the second photoelectric conversion unit 4 an amorphous photoelectric conversion unit similar to the first photoelectric conversion unit may be adopted, or a photoelectric conversion unit formed of silicon-based material including crystalline (silicon-based thin film) may be adopted.

In the second photoelectric conversion unit 4, the thickness of the p-layer 41 is, for example, 100 Å, the thickness of the i-layer 42 is, for example, 15000 Å, and the thickness of the n-layer 43 is, for example, 150 Å.

The p-layer 41, the i-layer 42, and the n-layer 43 of the second photoelectric conversion unit 4 are formed in a plurality of plasma CVD reaction chambers.

That is, in each of the plasma CVD reaction chambers which are different from each other, one layer constituting the first photoelectric conversion unit 103 is formed.

The back-face electrode 5 is formed of a light reflection film having conductivity such as Ag (silver), Al (aluminum), or the like.

The back-face electrode 5 is formed using, for example, a sputtering method or an evaporation method.

Additionally, as the structure of the back-face electrode 5, a layered structure may be adopted in which a film composed of a conductive oxidative product such as ITO, SnO₂, ZnO, or the like is formed between the n-layer 43 and the back-face electrode 5 of the second photoelectric conversion unit 4.

Manufacturing System

Next, a manufacturing system manufacturing the photoelectric conversion device 10 will be described with reference to drawings.

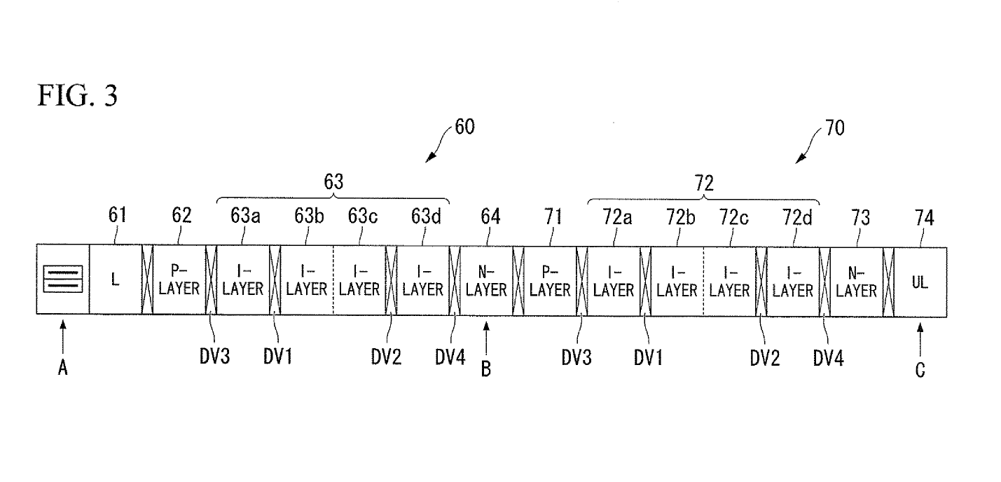

FIG. 3 is a cross-sectional view schematically showing a photoelectric conversion device manufacturing system related to the invention.

As shown in FIG. 3, the manufacturing system is constituted of a first film-formation apparatus 60 and a second film-formation apparatus 70 connected to the first film-formation apparatus 60.

The first film-formation apparatus 60 is an in-line type film-formation apparatus, in which a plurality of film-formation reaction chambers which are referred to as chamber are arranged so as to be linearly connected (linear configuration).

In the first film-formation apparatus 60, the first photoelectric conversion unit 3 is formed.

The p-layer 31, the i-layer 32, and the n-layer 33 constituting the first photoelectric conversion unit 3 are formed in the film-formation reaction chambers of the first film-formation apparatus 60.

In particular, one of the p-layer 31, the i-layer 32, and the n-layer 33 is formed in each of the film-formation reaction chambers which are different from each other.

The second film-formation apparatus 70 is an in-line type film-formation apparatus, in which a plurality of film-formation reaction chambers which are referred to as chamber are arranged so as to be linearly connected (linear configuration).

In the second film-formation apparatus 70, the second photoelectric conversion unit 4 is formed on the first photoelectric conversion unit 3.

The p-layer 41, the i-layer 42, and the n-layer 43 constituting the second photoelectric conversion unit 104 are formed in the film-formation reaction chambers of the second film-formation apparatus.

In particular, one of the p-layer 41, the i-layer 42, and the n-layer 43 is formed in each of the film-formation reaction chambers which are different from each other.

In the first film-formation apparatus 60, a load chamber 61 (L: Lord), a P-layer film-formation reaction chamber 62, an I-layer-formation reaction chamber 63, and an N-layer film-formation reaction chamber 64 are continuously and linearly arranged.

At the stage subsequent to the L chamber, a heating chamber may be provided which produce an increase in a temperature of the substrate to be constant temperature depending on conditions of a film formation process.

The substrate is transferred to the load chamber 61 and disposed therein, the inside of the load chamber 61 is depressurized.

The p-layer 31 of the first photoelectric conversion unit 3 is formed in the P-layer film-formation reaction chamber 62, the i-layer 32 is formed in the I-layer-formation reaction chamber 63, and the n-layer 33 is formed in the N-layer film-formation reaction chamber 64.

At the time, at the A point shown in FIG. 3, an insulative-transparent substrate 1 on which the transparent-electroconductive film 2 is formed is prepared as shown in FIG. 1A.

Additionally, at the B point shown in FIG. 3, a first intermediate part 10a of the photoelectric conversion device is formed on the transparent-electroconductive film 2 formed on the insulative-transparent substrate 1 as shown in FIG. 1B. In the first intermediate part 10a, the p-layer 31, the i-layer 32, and the n-layer 33 of the first photoelectric conversion unit 3 are provided.

In the second film-formation apparatus 70, a P-layer film-formation reaction chamber 71, an I-layer-formation reaction chamber 72, an N-layer film-formation reaction chamber 73, and an unload chamber 74 (UL: Unlord) are continuously and linearly arranged.

In the P-layer film-formation reaction chamber 71, the p-layer 41 of the second photoelectric conversion unit 4 is continuously formed on the n-layer 33 of the first photoelectric conversion unit 3. The n-layer 33 is formed in the first film-formation apparatus 60.

The i-layer 42 is formed in the I-layer-formation reaction chamber 72, and the n-layer 43 is formed in the N-layer film-formation reaction chamber 73.

The substrate on which the second photoelectric conversion unit 104 is formed is transferred to the unload chamber 74, and the inside pressure of the unload chamber 74 is returned to the atmospheric pressure.

Finally, the substrate is ejected from the unload chamber 74.

At the time, at the C point shown in FIG. 3, a second intermediate part 10b of the photoelectric conversion device is formed as shown in FIG. 1C. In the second intermediate part 10b, the second photoelectric conversion unit 4 is provided on the first photoelectric conversion unit 3.

Additionally, in the in-line type first film-formation apparatus 60 shown in FIG. 3, two substrates are processed at the same time.

The I-layer-formation reaction chamber 63 is constituted of four reaction chambers which are sequentially arranged along a transfer direction in which the substrate is transferred, that is, a reaction chamber 63a (first film formation section), a reaction chamber 63b (second film formation section), a reaction chamber 63c (second film formation section), and a reaction chamber 63d (third film formation section).

Furthermore, in the in-line type second film-formation apparatus 70, two substrates are processed at the same time.

The I-layer-formation reaction chamber 72 is four reaction chambers which are sequentially arranged along a transfer direction in which the substrate is transferred, that is, a reaction chamber 72a (first film formation section), a reaction chamber 72b (second film formation section), a reaction chamber 72c (second film formation section), and a reaction chamber 72d (third film formation section).

In the foregoing photoelectric conversion device manufacturing system of the embodiment, the I-layer-formation reaction chamber 63 is separated into at least three film formation sections (film formation space) by door valves DV.

Specifically, the I-layer film-formation reaction chamber 63 is separated into a first film formation section (reaction chamber 63a) located at a front position, a second film formation section (reaction chambers 63b and 63c) located at the middle position, and a third film formation section (reaction chamber 63d) located at rear position.

The door valve DV is disposed between the reaction chamber 63a and the reaction chamber 63b and between the reaction chamber 63c and the reaction chamber 63d, and the I-layer film-formation reaction chamber 63 is thereby divided into three film formation sections.

Furthermore, a door valve is not disposed between the reaction chamber 63b and the reaction chamber 63c, the reaction chambers 63b and 63c form one film formation section (second film formation section).

The length of the second film formation section is greater than the lengths of the first film formation section (reaction chamber 63a) and the third film formation section (reaction chamber 63d).

Specifically, the I-layer film-formation reaction chamber 63 includes a plurality of door valves DV1 and DV2.

The door valves DV separate the reaction chambers 63a, 63b, 63c, and 63d so that the total length of the reaction chambers 63b and 62c is greater than the lengths of the reaction chamber 63a and the reaction chamber 63d in the transfer direction in which the substrate 1 is transferred.

That is, the first door valve DV1 is provided between the reaction chamber 63a and the reaction chamber 63b.

The second door valve DV2 is provided between the reaction chamber 63c and the reaction chamber 63d.

Moreover, a third door valve DV3 (upstream door valve) is provided between the P-layer film-formation reaction chamber 62 and the I-layer-formation reaction chamber 63.

A fourth door valve DV4 (downstream door valve) is provided between the I-layer-formation reaction chamber 63 and the N-layer film-formation reaction chamber 64.

Furthermore, the I-layer film-formation reaction chamber 72 includes a plurality of door valves DV1 and DV2.

The door valves DV separate the reaction chambers 72a, 72b, 72c, and 72d so that the total length of the reaction chambers 72b and 62c is greater than the lengths of the reaction chamber 72a and the reaction chamber 72d in the transfer direction in which the substrate 1 is transferred.

That is, the first door valve DV1 is provided between the reaction chamber 72a and the reaction chamber 72b.

The second door valve DV2 is provided between the reaction chamber 72c and the reaction chamber 72d.

Moreover, a third door valve DV3 (upstream door valve) is provided between the P-layer film-formation reaction chamber 71 and the I-layer-formation reaction chamber 72.

A fourth door valve DV4 (downstream door valve) is provided between the I-layer-formation reaction chamber 72 and the N-layer film-formation reaction chamber 73.

In the following explanation, in order to describe the manufacturing system and the manufacturing method of the invention, the manufacturing method in the first film-formation apparatus 60 will be described; however, even in the second film-formation apparatus 70, the same manufacturing system is used and the same manufacturing method is applied.

In addition, in the above-described manufacturing system, a carrier is transferred from the film forming chambers 62 to the film forming chamber 73 in a state where the substrate 1 is held on the carrier, and the above-described semiconductor layers are layered on the substrate 1.

Consequently, in the invention, “the substrate being transferred” means a substrate attached to the carrier being transferred with the carrier.

Furthermore, an opening section is provided at the carrier, and semiconductor layers are layered only on an exposed region of the substrate 1 in a state where a part of the substrate 1 is exposed.

In the manufacturing system of the embodiment having the foregoing structure, it is possible to completely separate the second film formation section (reaction chambers 63b and 63c) located at the middle position in the three film formation sections, the film formation section (P-layer film-formation reaction chamber 62) which is located in front of the I-layer film-formation reaction chamber 63 and in which a p-layer is formed, and the film formation section (N-layer film-formation reaction chamber 64) which is located in the rear of the I-layer-formation reaction chamber 63 and in which an n-layer is formed.

For this reason, it is possible to form the i-layer in the second film formation section located at the middle position between the first film formation section and the third film formation section, in a state where the amount of impurities therein is less than that of the first film formation section and the third film formation section.

Additionally, in the manufacturing system of the embodiment, the length of the second film formation section is greater than the lengths of the first film formation section (a film formation space which is located at a front position) and the third film formation section (a film formation space which is located at a rear position).

For this reason, the volume of the second film formation section is greater than the volumes of the first film formation section and the third film formation section.

Therefore, as compared with a conventional apparatus that is provided with a plurality of film forming chambers separated by the door valves, it is possible to eliminate the difference in pressure which is caused by an opening-closing operation of the door valves, and it is possible to form a film under stabilized pressure.

Furthermore, occurrence of the time loss which is caused by an opening-closing operation of the door valves can be prevented, even when film formation is stopped, it is possible to achieve a high throughput.

Additionally, it is possible to reduce the number of chamber mechanism such as an evacuation mechanism or the like due to reducing the number of door valves, and it is possible to reduce the cost of the apparatus or the risk of the apparatus breaking down.

Manufacturing Method

Next, a method for manufacturing the photoelectric conversion device 10 using the above-described photoelectric conversion device manufacturing system will be described.

Firstly, as shown in FIG. 1A, an insulative-transparent substrate 1 on which the transparent-electroconductive film 2 is formed is prepared.

Next, as shown in FIG. 1B, the p-layer 31, the i-layer 32, and the n-layer 33 constituting the first photoelectric conversion unit 3 are formed on the transparent-electroconductive film 2 formed on the insulative-transparent substrate 1 using a plurality of plasma CVD reaction chambers.

Specifically, one p-layer 31 is formed in one P-layer film-formation reaction chamber 62, thereafter, an i-layer 32 is layered thereon in subsequent I-layer-formation reaction chamber 63.

In the same manner as in the above method, an n-layer 33 is layered in subsequent N-layer film-formation reaction chamber 64.

As mentioned above, the substrate 1 is transferred through a plurality of plasma CVD reaction chambers and each layer is formed thereon, therefore, the p-layer 31, the i-layer 32, and the n-layer 33 are layered on the transparent-electroconductive film 2 of the substrate 1.

Consequently, the first intermediate part 10a of the photoelectric conversion device is formed.

In the method for forming the p-layer 31, it is possible to form a p-layer made of amorphous silicon (a-Si), for example, under the following conditions using a plasma CVD method.

Specifically, the substrate temperature is 180 to 200° C., the frequency of the power source is 13.56 MHz, the internal pressure of the reaction chamber is 70 to 120 Pa, and the flow rates of the reactive gases are 300 sccm of monosilane (SiH₄), 2300 sccm of hydrogen (H₂), 180 sccm of diborane (B₂H₆/H₂) using hydrogen as a diluted gas, and 500 sccm of methane (CH₄).

Additionally, in the method for forming the i-layer 32, it is possible to form an i-layer made of amorphous silicon (a-Si), for example, under the following conditions using a plasma CVD method.

Specifically, the substrate temperature is 180 to 200° C., the frequency of the power source is 13.56 MHz, the internal pressure of the reaction chamber is 70 to 120 Pa, and the flow rate of the reactive gas is 1200 sccm of monosilane (SiH₄).

Furthermore, in the method for forming the n-layer 33, it is possible to form an n-layer made of amorphous silicon (a-Si), for example, under the following conditions using a plasma CVD method.

Specifically, the substrate temperature is 180 to 200° C., the frequency of the power source is 13.56 MHz, the internal pressure of the reaction chamber is 70 to 120 Pa, and the flow rate of the reactive gas is 200 sccm of phosphine (PH₃/H₂) using hydrogen as a diluted gas.

Continuously, as shown in FIG. 1C, the p-layer 41, and the i-layer 42, and the n-layer 43 constituting the second photoelectric conversion unit 4 are formed on the n-layer 33 of the first photoelectric conversion unit 3 using a plurality of plasma CVD reaction chambers.

Specifically, one p-layer 41 is formed in one P-layer film-formation reaction chamber 71, thereafter, an i-layer 42 is layered thereon in subsequent I-layer-formation reaction chamber 72.

In the same manner as in the above method, an n-layer 43 is layered in subsequent N-layer film-formation reaction chamber 73.

As mentioned above, the substrate 1 is transferred through a plurality of plasma CVD reaction chambers and each layer is formed thereon, therefore, the second intermediate part 10b of the photoelectric conversion device on which the second photoelectric conversion unit 4 is provided on the first photoelectric conversion unit 3.

Furthermore, by forming the back-face electrode 5 on the n-layer 43 of the second photoelectric conversion unit 4, the photoelectric conversion device 10 is obtained as shown in FIG. 2.

In the method for forming the p-layer 41, it is possible to form a p-layer made of microcrystalline silicon (μc-Si), for example, under the following conditions using a plasma CVD method.

Specifically, the substrate temperature is 180 to 200° C., the frequency of the power source is 13.56 MHz, the internal pressure of the reaction chamber is 500 to 900 Pa, and the flow rates of the reactive gases are 100 sccm of monosilane (SiH₄), 25000 sccm of hydrogen (H₂), and 50 sccm of diborane (B₂H₆/H₂) using hydrogen as a diluted gas.

In the method for forming the i-layer 42, it is possible to form an i-layer made of microcrystalline silicon (μc-Si), for example, under the following conditions using a plasma CVD method.

Specifically, the substrate temperature is 180 to 200° C., the frequency of the power source is 13.56 MHz, the internal pressure of the reaction chamber is 500 to 900 Pa, and the flow rates of the reactive gas are 180 sccm of monosilane (SiH₄) and 27000 sccm of hydrogen (H₂).

In the method for forming the n-layer 43, it is possible to form an n-layer made of microcrystalline silicon (μc-Si), for example, under the following conditions using a plasma CVD method.

Specifically, the substrate temperature is 180 to 200° C., the frequency of the power source is 13.56 MHz, the internal pressure of the reaction chamber is 500 to 900 Pa, and the flow rates of the reactive gas are 180 sccm of monosilane (SiH₄), 27000 sccm of hydrogen (H₂), and 200 sccm of phosphine (PH₃/H₂) using hydrogen as a diluted gas.

Specifically, in the manufacturing method of the embodiment, the semiconductor layers are formed on the substrate 1 by use of the above-described manufacturing system as stated mentioned below.

Specifically, in the manufacturing method of the embodiment, the i-layer is formed in the second film formation section (reaction chambers 63b and 63c) in a state where the first door valve DV1 disposed between the first film formation section (reaction chamber 63a) and the second film formation section (reaction chamber 63b) and the second door valve DV2 disposed between the second film formation section (reaction chamber 63c) and the third film formation section (reaction chamber 63d) are closed.

Additionally, the third door valve DV3 is opened during the i-layer being formed in the second film formation section (reaction chambers 63b and 63c), and the substrate 1 is transferred from the P-layer film-formation reaction chamber 62 to the film formation section (e.g., first film formation section) different from the second film formation section.

Furthermore, the fourth door valve DV4 is opened during the i-layer being formed in the second film formation section (reaction chambers 63b and 63c), and the substrate 1 is transferred to N-layer film-formation reaction chamber 64 from the film formation section (e.g., third film formation section) different from the second film formation section.

Hereinbelow, an operation of transferring a carrier holding the substrate 1 and an operation in each of the above-described film forming chambers will be described with reference to drawings.

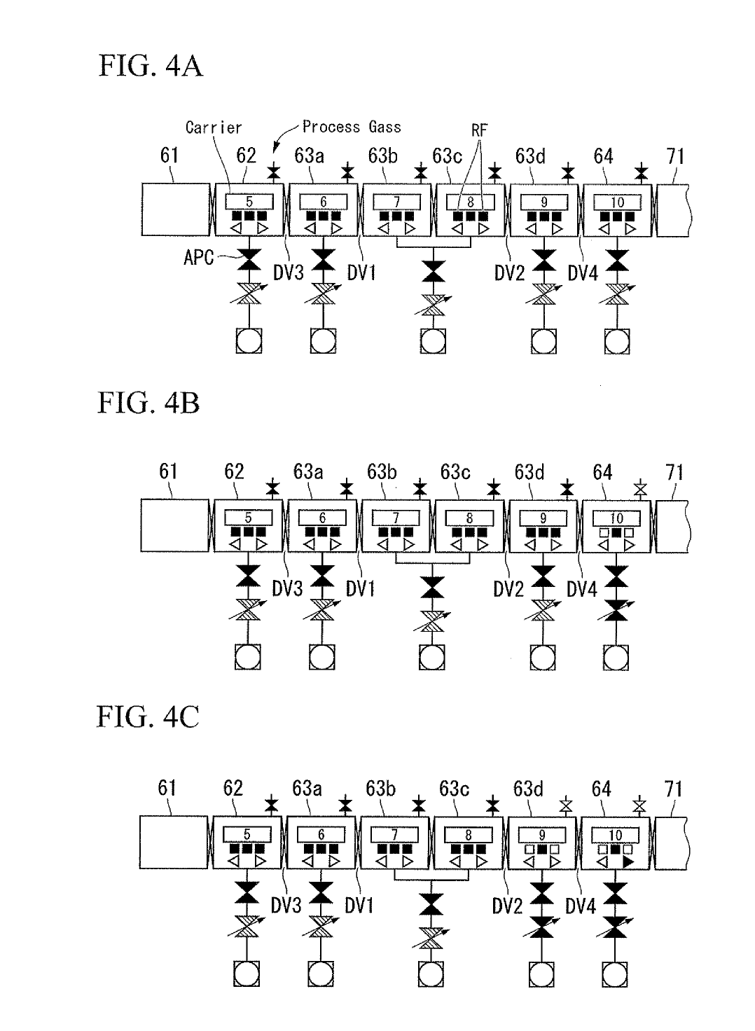

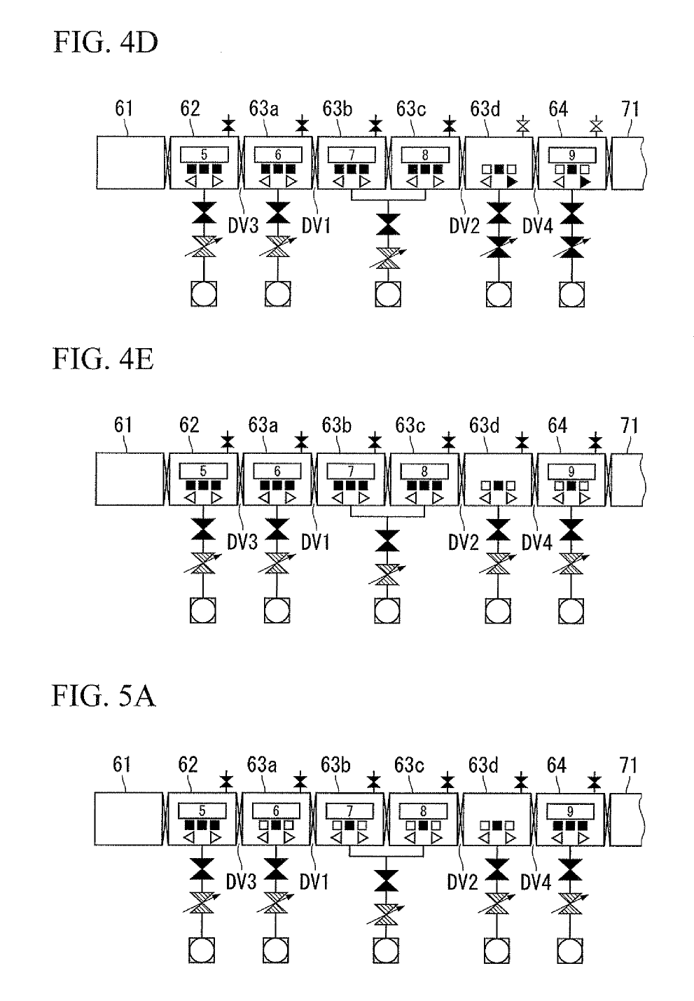

FIGS. 4A to 6B are a cross-sectional view illustrating an operation in each reaction chamber of the manufacturing system of the invention.

In the following explanation, the manufacturing method in the first film-formation apparatus 60 will be described; however, even in the second film-formation apparatus 70, it is possible to perform a film formation step using the same operating method as in the first film-formation apparatus 60.

FIGS. 4A to 6B, members indicated by reference numerals 4 to 10 represent carriers.

That is, a state where the carrier indicated by reference numerals 4 to 10 are placed in the reaction chambers 62 to 64 is shown.

Moreover, symbols which are represented by three tetragons are aligned in each of the reaction chambers 62 to 64.

The three tetragons indicate the operation condition of a first RF power supply, the operation condition of a heater, and the operation condition of and a second RF power supply in each reaction chamber.

In the tetragons, the black colored tetragon (closed tetragon) indicates an “ON” condition, and the tetragon represented by a solid line (open tetragon) indicates an “OFF” condition.

In addition, when both the first RF power supply and the second RF power supply are ON, it means that both substrates attached to the carrier disposed in the reaction chamber are being subjected to film formation process.

Furthermore, symbols which are represented by two triangles are aligned in each of the reaction chambers 62 to 64.

In particular, the first triangle having angle portions at the right side thereof and having a line portion at the left side thereof, and the second triangle having angle portions at the left side thereof and having a line portion at the right side thereof are aligned.

The symbols represented by the two triangles indicate the transferring method of the carrier in each reaction chamber.

For example, in the case where the triangle (open triangle) represented by a solid line is turned to the black colored triangle (closed triangle) at the first triangle having angle portions at the right side thereof and having a line portion at the left side thereof, it means that the operation of transferring the carrier in the right direction is performed.

Additionally, a gas valve (Process Gas) and a pressure control valve (APC) are connected to each of the reaction chambers 62 to 64.

The gas valve represented by in black (closed) means a degree of valve opening being 100%, that is, being a full-opened condition.

Furthermore, the gas valve represented by a solid line (open) means a degree of valve opening being 0%, that is, being a complete-closed condition.

Moreover, in the pressure control valve, the condition represented in black (closed) means a degree of opening of the pressure control valve being 100%, that is, being a full-opened condition.

Additionally, the pressure control valve represented by hatching means a state where the inside pressure of the reaction chamber is controlled depending on a gas flow rate.

Hereinbelow, the manufacturing method of the embodiment in the first film-formation apparatus 60 will be described.

(1) Firstly, as shown in FIG. 4A, a film formation step is performed in all reaction chambers constituting the first film-formation apparatus.

That is, the p-layer 31 is formed on the substrate attached to carrier No. 5 in the P-layer film-formation reaction chamber 62.

The i-layer 32 is formed on the substrates attached to carriers No. 6 to No. 9 in the reaction chambers 63a to 63d.

Moreover, the n-layer 33 is formed on the substrate attached to carrier No. 10 in the N-layer film-formation reaction chamber 64.

In addition, a transparent-electroconductive film is formed in advance on the substrate attached to the carrier shown in FIGS. 4A to 6B.

The I-layer-formation reaction chamber 63 (reaction chambers 63a to 63d) is divided into at least three film formation sections by the first door valve DV1 and the second door valve DV2.

In the embodiment, the I-layer film-formation reaction chamber 63 is separated into the reaction chamber 63a serving as the first film formation section, the reaction chambers 63b and 63c serving as the second film formation section and the reaction chamber 63d serving as the third film formation section.

The first door valve DV1 is provided between the reaction chamber 63a and the reaction chamber 63b.

The second door valve DV2 is provided between the reaction chamber 63c and the reaction chamber 63d.

On the other hand, a door valve is not provided between the reaction chambers 63b and 63c.

Consequently, the second film formation section (reaction chambers 63b and 63c) located at the middle position between the first film formation section and the third film formation section can be completely separated from the P-layer film-formation reaction chamber 62 and the N-layer film-formation reaction chamber 64.

For this reason, it is possible to form the i-layer with a low amount of impurities in the second film formation section (reaction chambers 63b and 63c) in which the amount of impurities is less than that of the first film formation section and the third film formation section.

(2) Next, as shown in FIG. 4B, the step of forming the n-layer 33 on the substrate attached to carrier No. 10 is completed (RF: OFF) in the N-layer film-formation reaction chamber 64.

The gas valve of the N-layer film-formation reaction chamber 64 is closed, and the gas existing inside the N-layer film-formation reaction chamber 64 is removed (vacuuming exhaust).

(3) Subsequently, as shown in FIG. 4C, carrier No. 10 disposed in the N-layer film-formation reaction chamber 64 is transferred to the P-layer film-formation reaction chamber 71 of the second film-formation apparatus 70 (right direction transfer).

On the other hand, in the reaction chamber 63d, the film formation step of the i-layer 32 on the substrate attached to carrier No. 9 is completed (RF: OFF).

The gas existing inside the reaction chamber 63d is removed.

(4) Next, as shown in FIG. 4D, carrier No. 10 is transferred from the reaction chamber 64 to the P-layer film-formation reaction chamber 71 of the second film-formation apparatus 70.

Additionally, the fourth door valve DV4 is opened, and carrier No. 9 is transferred from the reaction chamber 63d to the N-layer film-formation reaction chamber 64.

During the foregoing transferring step being performed, the step of forming the i-layer 32 on the substrates attached to carriers No. 7 and No. 8 is performed in the reaction chambers 63b and 63c in a state where the door valves DV1 and DV2 are being closed.

That is, the fourth door valve DV4 is opened during the i-layer 32 being formed in the reaction chambers 63b and 63c, and the substrate is transferred to the N-layer film-formation reaction chamber 64 from the reaction chamber 63d different from the reaction chambers 63b and 63c.

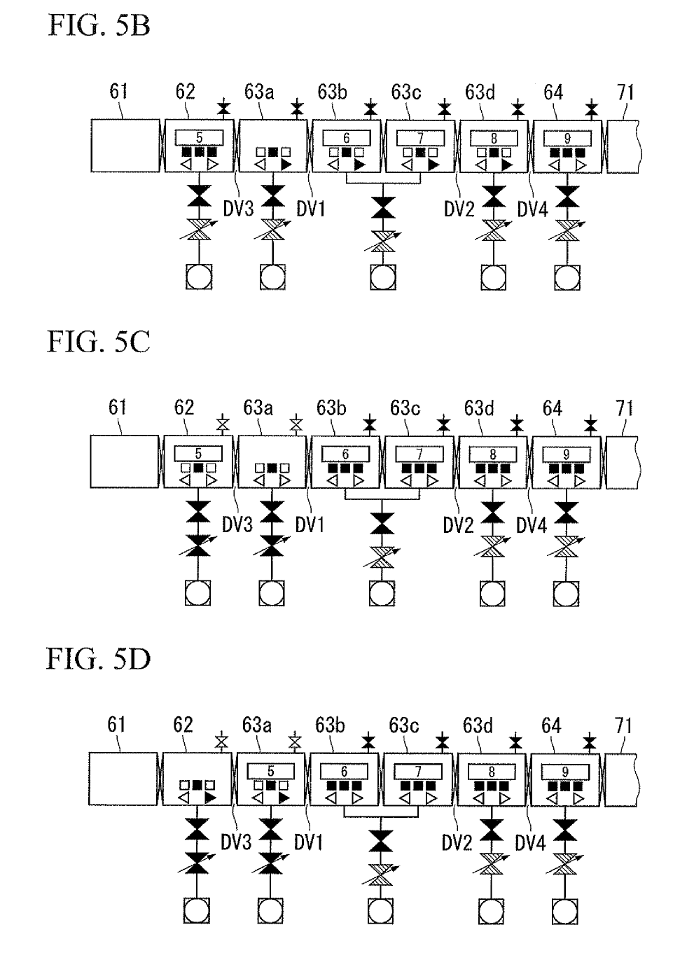

(5) Subsequently, as shown in FIG. 4E, each of the pressures of the reaction chamber 63d and the N-layer film-formation reaction chamber 64 is controlled in accordance with the film forming condition.
(6) Next, as shown in FIG. 5A, the step of forming the n-layer 33 on the substrate attached to carrier No. 9 is started (RF: ON) in the N-layer film-formation reaction chamber 64.

On the other hand, the step of forming the i-layer 32 is completed (RF: OFF) in the reaction chambers 63a to 63c.

(7) Subsequently, as shown in FIG. 5B, carriers No. 6, No. 7, and No. 8 are transferred to a reaction chamber in which subsequent step is performed.

That is, carrier No. 8 is transferred from the reaction chamber 63c to the reaction chamber 63d, carrier No. 7 is transferred from the reaction chamber 63b to the reaction chamber 63c, and carrier No. 6 is transferred from the reaction chamber 63a to the reaction chamber 63b.

(8) Next, as shown in FIG. 5C, the step of forming the i-layer 32 on the substrate attached to carriers No. 6 to No. 8 is started (RF: ON) in the reaction chambers 63b to 63d.

On the other hand, the gas valve of the reaction chamber 63a is closed, and the gas existing inside the reaction chamber 63a is removed in the reaction chamber 63a.

Additionally, in the P-layer film-formation reaction chamber 62, the step of forming the p-layer 31 on the substrate attached to carrier No. 5 is completed (RF: OFF), the gas valve of the P-layer film-formation reaction chamber 62 is closed, and the gas existing inside the P-layer film-formation reaction chamber 62 is removed.

(9) Subsequently, as shown in FIG. 5D, the third door valve DV3 is opened, carrier No. 5 is transferred from the P-layer film-formation reaction chamber 62 to the reaction chamber 63a.

During the foregoing transferring step being performed, the step of forming the i-layer 32 on the substrates attached to carriers No. 6 and No. 7 is performed in the reaction chambers 63b and 63c in a state where the door valves DV1 and DV2 are being closed.

That is, the third door valve DV3 is opened during the i-layer 32 being formed in the reaction chambers 63b and 63c, and the substrate is transferred from the P-layer film-formation reaction chamber 62 to the reaction chamber 63a different from the reaction chambers 63b and 63c.

(10) Next, as shown in FIG. 5E, the pressure of the reaction chamber 63a is controlled in accordance with the film forming condition.

Furthermore, carrier No. 4 having a substrate on which a p-layer 31 is not formed is newly transferred to the P-layer film-formation reaction chamber 62.

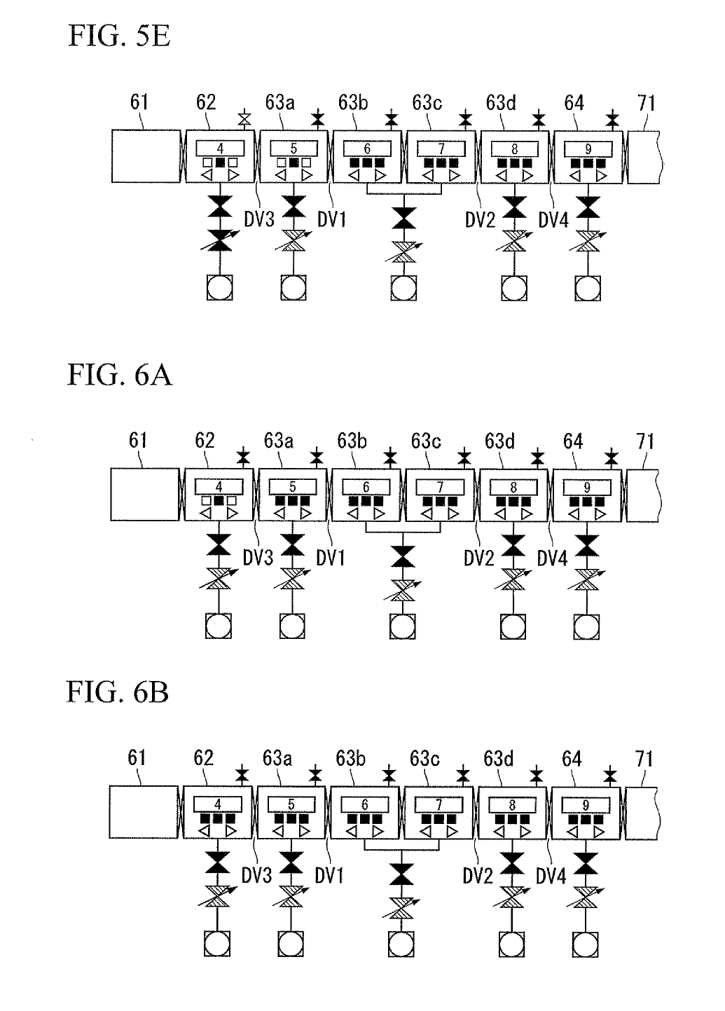

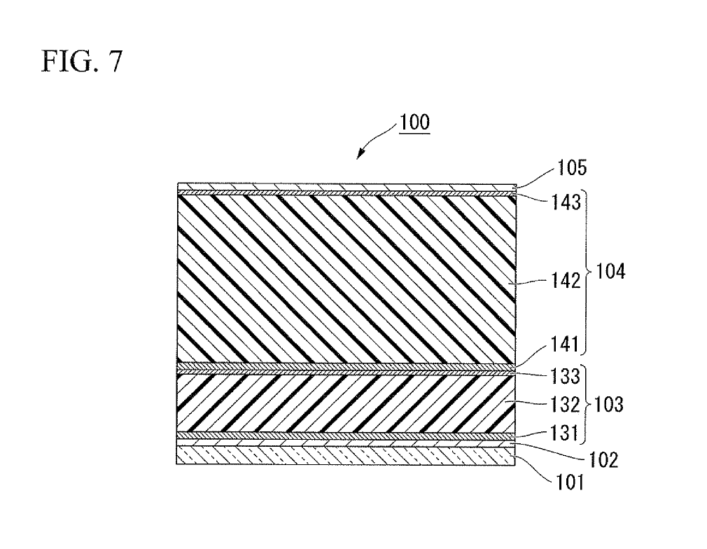

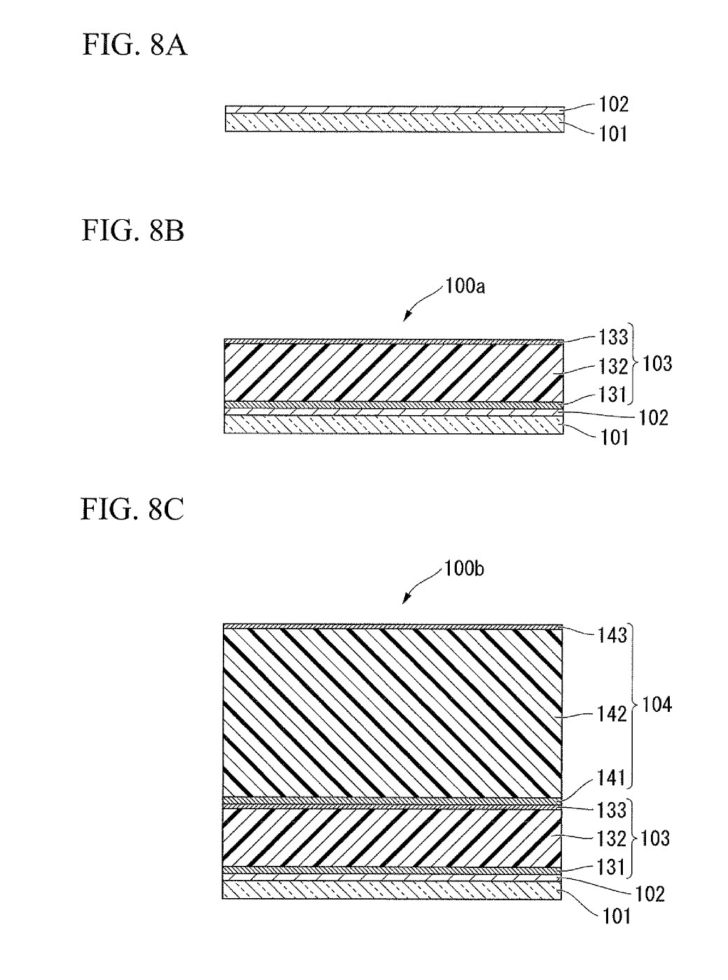

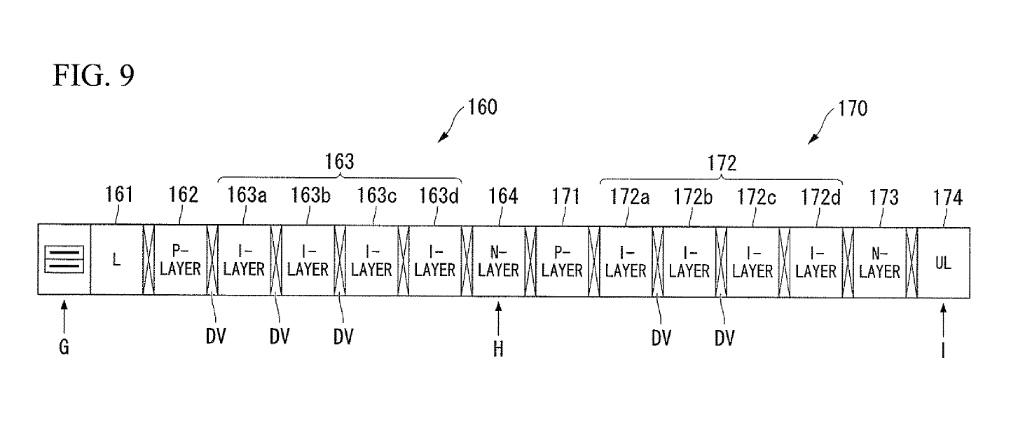

(11) Subsequently, as shown in FIG. 6A, the step of forming the i-layer 32 on the substrate attached to carrier No. 5 is started (RF: ON) in the reaction chamber 63a.

Moreover, the pressure of the P-layer film-formation reaction chamber 62 is controlled in accordance with the film forming condition.

(12) Consequently, as shown in FIG. 6B, the step of forming the p-layer 31 on the substrate attached to carrier No. 4 is started (RF: ON) in the P-layer film-formation reaction chamber 62.

Through the above-described series of operation, the p-layer 31, the i-layer 32, and the n-layer 33 of the first photoelectric conversion unit 3 are sequentially formed on the substrate.

In the embodiment as described above, it is possible to completely separate the second film formation section (reaction chambers 63b and 63c) located at the middle position in three film formation sections, from the film formation section (reaction chamber 62) in which the p-layer is formed and from the film formation section (reaction chamber 64) in which the n-layer is formed.

Because of this, it is possible to form the i-layer in the second film formation section (reaction chambers 63b and 63c) in a state where the amount of impurities therein is less than that of the first film formation section (reaction chamber 63a) and the third film formation section 63d.

Additionally, the third door valve DV3 is opened during the i-layer being formed in the reaction chambers 63b and 63c, and the substrate is transferred from the P-layer film-formation reaction chamber 62 to the reaction chamber 63a.

For this reason, the film formation step in the reaction chambers 63b and 63c and the step of transferring the substrate from the P-layer film-formation reaction chamber 62 to the reaction chamber 63a can be simultaneously performed.

Additionally, the fourth door valve DV4 is opened during the i-layer being formed in the reaction chambers 63b and 63c, and the substrate is transferred from the reaction chamber 63d to the N-layer film-formation reaction chamber 64.

Because of this, the film formation step in the reaction chambers 63b and 63c and the step of transferring the substrate from the reaction chamber 63d to the N-layer film-formation reaction chamber 64 can be simultaneously performed.

For this reason, it is possible to perform the film formation step while the reaction chambers 63b and 63c are completely separated from the reaction chambers 63a and 63d.

Because of this, it is possible to form the i-layer in the second film formation section (reaction chambers 63b and 63c) in a state where the amount of impurities therein is less than that of the first film formation section (reaction chamber 63a) and the third film formation section 63d.

Furthermore, the length of the second film formation section (the total length of the reaction chambers 63b and 63c) is greater than the lengths of the first film formation section (reaction chamber 63a) and the third film formation section (reaction chamber 63d).

For this reason, the volume of the second film formation section is greater than the volumes of the first film formation section and the third film formation section.

Therefore, as compared with a conventional apparatus that is provided with a plurality of film forming chambers separated by the door valves, it is possible to eliminate the difference in pressure which is caused by an opening-closing operation of the door valves, and it is possible to form a film under stabilized pressure.

Additionally, it is possible to reduce the risk that aerial current is generated at the time of opening the door valve, and a film which has already adhered to an inner wall of the film forming chamber is peeled off or particles flying in all directions, which are caused by a decrease in the number of door valves.

Furthermore, occurrence of the time loss which is caused by an opening-closing operation of the door valves can be prevented, even when film formation is stopped, it is possible to achieve a high throughput.

As described above, the photoelectric conversion device manufacturing system and the photoelectric conversion device manufacturing method of the invention are described.

The technical scope of the invention is not limited to the above embodiments, but various modifications may be made without departing from the scope of the invention.

For example, a front reaction chamber may be provided between the P-layer film-formation reaction chamber 62 and the reaction chamber 63a; the front reaction chamber corresponds to a film formation section which is different from the second film formation section, and an i-layer is formed in the front reaction chamber.

In this case, an upstream door valve is provided between the front reaction chamber and the P-layer film-formation reaction chamber 62.

Even in this case, the upstream door valve is opened during the film formation step being performed in the reaction chambers 63b and 63c, and it is possible to transfer a substrate from the P-layer film-formation reaction chamber 62 to the front reaction chamber.

Moreover, a rear reaction chamber may be provided between the N-layer film-formation reaction chamber 64 and the reaction chamber 63d; the rear reaction chamber corresponds to a film formation section which is different from the second film formation section, and an i-layer is formed in the rear reaction chamber.

In this case, a downstream door valve is provided between the rear reaction chamber and the N-layer film-formation reaction chamber 64.

Even in this case, the downstream door valve is opened during the film formation step being performed in the reaction chambers 63b and 63c, and it is possible to transfer a substrate from the rear reaction chamber to the N-layer film-formation reaction chamber 64.

In addition, in the aforementioned embodiment, the case where two reaction chambers 63b and 63c constitute the second film formation section is illustrated; but three or more reaction chambers may constitute the second film formation section.

Furthermore, the length of one reaction chamber corresponding to the second film formation section may be greater than the length of the reaction chamber corresponding to the first film formation section and the third film formation section.

### INDUSTRIAL APPLICABILITY

The invention is widely applicable to a photoelectric conversion device manufacturing system and a photoelectric conversion device manufacturing method.

What is claimed is:

1. A photoelectric conversion device manufacturing system in which a photoelectric conversion device is manufactured, the photoelectric conversion device comprising a p-type semiconductor layer, an i-type semiconductor layer, and an n-type semiconductor layer which are sequentially layered on a transparent-electroconductive film formed on a substrate in the photoelectric conversion device, the system comprising:
an i-layer-formation reaction chamber comprising at least a first film formation section, a second film formation section, and a third film formation section, the i-layer-formation reaction chamber forming the i-type semiconductor layer, the first film formation section, the second film formation section, and the third film formation section being sequentially arranged along a transfer direction in which the substrate is transferred; and
a plurality of door valves separating the first film formation section, the second film formation section, and the third film formation section so that the length of the second film formation section is greater than the lengths of the first film formation section and the third film formation section in the transfer direction.

2. A photoelectric conversion device manufacturing method in which a photoelectric conversion device is manufactured, the photoelectric conversion device comprising a p-type semiconductor layer, an i-type semiconductor layer, and an n-type semiconductor layer which are sequentially layered on a transparent-electroconductive film formed on a substrate in the photoelectric conversion device, the method comprising:
preparing an i-layer film-formation reaction chamber comprising at least a first film formation section, a second film formation section, and a third film formation section which are sequentially arranged along a transfer direction in which the substrate is transferred;
preparing a plurality of door valves separating the first film formation section, the second film formation section, and the third film formation section so that the length of the second film formation section is greater than the lengths of the first film formation section and the third film formation section in the transfer direction; and
forming the i-type semiconductor layer in the second film formation section in a state where the door valve disposed between the first film formation section and the second film formation section and the door valve disposed between the second film formation section and the third film formation section are closed.

3. The photoelectric conversion device manufacturing method according to claim 2, further comprising:
preparing a p-layer film-formation reaction chamber connected to the i-layer-formation reaction chamber at the upstream side in the transfer direction and an upstream door valve provided between the i-layer film-formation reaction chamber and the p-layer film-formation reaction chamber, wherein
the upstream door valve is opened and the substrate is transferred from the p-layer film-formation reaction chamber to a film formation section different from the second film formation section during the i-type semiconductor layer being formed in the second film formation section.

4. The photoelectric conversion device manufacturing method according to claim 3, wherein
the film formation section different from the second film formation section is the first film formation section.

5. The photoelectric conversion device manufacturing method according to claim 2, further comprising
preparing an n-layer film-formation reaction chamber connected to the i-layer-formation reaction chamber at the downstream side in the transfer direction and a downstream door valve provided between the i-layer film-formation reaction chamber and the n-layer film-formation reaction chamber, wherein
the downstream door valve is opened and the substrate is transferred from a film formation section different from the second film formation section to the n-layer film-formation reaction chamber during the i-type semiconductor layer being formed in the second film formation section.

6. The photoelectric conversion device manufacturing method according to claim 5, wherein
the film formation section different from the second film formation section is the third film formation section.
